(19) United States
(12) Patent Application Publication
(10) Pub. No.: US 2026/0038619 A1
(43) Pub. Date: Feb. 5, 2026

(54) SEMICONDUCTOR DEVICE PERFORMING TESTS AND TEST METHOD OF THE SEMICONDUCTOR DEVICE

(71) Applicant: SK hynix Inc., Icheon-si Gyeonggi-do (KR)

(72) Inventor: Choung Ki SONG, Icheon-si Gyeonggi-do (KR)

(73) Assignee: SK hynix Inc., Icheon-si Gyeonggi-do (KR)

(21) Appl. No.: 19/285,899

(22) Filed: Jul. 30, 2025

(30) Foreign Application Priority Data
Aug. 1, 2024 (KR) 10-2024-0102589
Feb. 24, 2025 (KR) 10-2025-0023974
Jul. 16, 2025 (KR) 10-2025-0096412

(51) Int. Cl. G11C 29/38; G11C 29/02; G11C 29/12; G11C 29/14

(52) U.S. Cl. CPC G11C 29/38; G11C 29/022; G11C 29/1201; G11C 29/14

(57) ABSTRACT

A semiconductor device includes a test control circuit generating an external output test pattern based on a test enable signal, an internal output test pattern and an output command signal based on an external input test pattern, and a check result signal based on input read data, an external input/output (IO) circuit generating the external input test pattern by performing a loopback operation based on the external output test pattern, an internal IO circuit generating an internal input test pattern based on the internal output test pattern and an input command signal based on the output command signal and outputting the input read data based on output read data, and a storage circuit storing the internal input test pattern based on the internal input test pattern and the input command signal and extracting the output read data based on the internal input test pattern and the input command signal.

### CROSS-REFERENCE TO RELATED APPLICATIONS

The present application claims priority under 35 U.S.C. § 119(a) to Korean Patent Application No. 10-2024-0102589, filed on Aug. 1, 2024, Korean Patent Application No. 10-2025-0023974, filed on Feb. 24, 2025, and Korean Patent Application No. 10-2025-0096412, filed on Jul. 16, 2025, which applications are incorporated herein by reference in their entirety.

### BACKGROUND

### 1. Technical Field

The present disclosure generally relates to a semiconductor device, and more particularly, to a semiconductor device configured to perform tests and a test method of the semiconductor device.

### 2. Background

Recently, a stack memory system, such as high bandwidth memory (HBM), is used in wide application fields due to its excellent bandwidth. Unlike the existing memory system using a parallel data bus, the stack memory system includes a stack memory device including a base die and core dies that are connected by through silicon vias (TSVs). The stack memory device includes a physical interface, such as a physical layer, for communication with a processor. The physical layer needs to be designed in order to guarantee high-speed data transmission and efficient communication.

The stack memory system uses a loopback test in order to check whether a connection of the physical layer and an input and output path is poor.

### SUMMARY

In an embodiment, a semiconductor device may include a test control circuit configured to generate an external output test pattern based on a test enable signal. The test control circuit may be configured to generate an internal output test pattern and an output command signal based on an external input test pattern. The test control circuit may be configured to generate a check result signal based on input read data. The semiconductor device may include an external input and output (IO) circuit configured to generate the external input test pattern by performing a loopback operation based on the external output test pattern. The semiconductor device may include an internal IO circuit configured to generate an internal input test pattern based on the internal output test pattern. The internal IO circuit may be configured to generate an input command signal based on the output command signal. The internal IO circuit may be configured to output the input read data based on output read data. The semiconductor device may include a storage circuit configured to store the internal input test pattern based on the internal input test pattern and the input command signal and configured to extract the output read data based on the internal input test pattern and the input command signal.

In an embodiment, a memory system may include a plurality of die cores stacked over a base die. The base die may include a test control circuit configured to generate an external output test pattern based on a test enable signal. The base die may be configured to generate an internal output test pattern and an output command signal based on an external input test pattern. The base die may be configured to generate a check result signal based on input read data, an external input and output (IO) circuit configured to generate the external input test pattern by performing a loopback operation based on the external output test pattern. The memory system may include an internal IO circuit configured to generate an internal input test pattern based on the internal output test pattern. the internal IO circuit may be configured to generate an input command signal based on the output command signal. The internal IO circuit may be configured to output the input read data based on output read data. Each of the plurality of die cores stores the internal input test pattern based on the internal input test pattern and the input command signal and outputs the output read data based on the internal input test pattern and the input command signal.

In an embodiment, a semiconductor device may include a test control circuit configured to generate an internal output test pattern and an output command signal based on a test enable signal. The test control circuit may be configured to generate a check result signal based on input read data. The semiconductor device may include an internal input and output (IO) circuit configured to generate an internal input test pattern based on the internal output test pattern. The IO circuit may be configured to generate an input command signal based on the output command signal. The IO circuit may be configured to output the input read data based on output read data. The semiconductor device may include a storage circuit configured to store the internal input test pattern based on the internal input test pattern and the input command signal. The storage circuit may be configured to output the output read data based on the internal input test pattern and the input command signal.

In an embodiment, a memory system may include a plurality of die cores stacked over a base die. The base die may include a test control circuit configured to generate an internal output test pattern and an output command signal based on a test enable signal. The test control circuit may be configured to generate a check result signal based on input read data. The base die may include an internal input and output (IO) circuit configured to generate an internal input test pattern based on the internal output test pattern. The IO circuit may be configured to generate an input command signal based on the output command signal. The IO circuit may be configured to output the input read data based on output read data. Each of the plurality of die cores comprises a storage circuit configured to store the internal input test pattern based on the internal input test pattern and the input command signal and configured to output the output read data based on the internal input test pattern and the input command signal.

In an embodiment, a method of checking whether a data input and output (IO) path and a memory cell are poor may include a first operation determination process of determining whether a command signal corresponds to a write operation or a read operation by entering a test mode based on a test enable signal. The method may include a first write process of generating a test pattern for the write operation and performing a loopback operation when the command signal is determined to correspond to the write operation and storing a test pattern for the write operation in a storage circuit. the method may include a first read process of generating a test pattern for the read operation and performing a loopback operation when the command signal is determined to correspond to the read operation and extracting read data from the storage circuit. The method may include a first check process of performing a check operation of checking whether a data input and output (IO) path and a memory cell are poor by outputting a check result signal based on whether the test pattern for the write operation and the read data are identical with each other when the first read process is completed. The method may include a first termination determination process of re-entering the first operation determination process when the test enable signal is determined to have been activated and terminating the test mode when the test enable signal is determined to have been deactivated, when the first write process or the first read process is completed.

In an embodiment, a method of checking whether a data input and output (IO) path and a memory cell are poor may include a second operation determination process of entering a test mode based on a test enable signal and determining whether a command signal corresponds to a write operation or a read operation. The method may include a second write process of generating a test pattern for the write operation within a semiconductor device and storing write data in a storage circuit when the command signal is determined to correspond to the write operation. The method may include a second read process of generating a test pattern for the read operation within the semiconductor device and extracting read data from the storage circuit when the command signal is determined to correspond to the read operation. The method may include a second check process of performing a check operation of checking whether a data IO path and a memory cell are poor by outputting a check result signal based on whether the write data and the read data are identical with each other when the second read process is completed. The method may include a second termination determination process of re-entering the second operation determination process when the test enable signal is determined to have been activated and terminating the test mode when the test enable signal is determined to have been deactivated, when the second write process or the second read process is completed.

### BRIEF DESCRIPTION OF THE DRAWINGS

FIG. 1 is a block diagram illustrating a semiconductor device according to an embodiment of the present disclosure.

FIG. 2 is a block diagram illustrating a test control circuit according to an embodiment of the present disclosure.

FIG. 3 is a block diagram illustrating an external input and output circuit according to an embodiment of the present disclosure.

FIG. 4 is a block diagram illustrating an internal input and

output circuit according to an embodiment of the present disclosure.

FIG. 5 is a block diagram illustrating a semiconductor device according to an embodiment of the present disclosure.

FIG. 6 is a block diagram illustrating a test control circuit according to an embodiment of the present disclosure.

FIG. 7 is a block diagram illustrating an internal input and output circuit according to an embodiment of the present disclosure.

FIG. 8 is a block diagram illustrating a memory system according to an embodiment of the present disclosure.

FIG. 9 illustrates the paths of a test pattern in the memory device according to an embodiment of the present disclosure.

FIG. 10 illustrates the paths of a test pattern in the memory device according to an embodiment of the present disclosure.

FIG. 11 is a flowchart describing a method of checking whether a data input and output path and a memory cell are poor within the memory system according to an embodiment of the present disclosure.

FIG. 12 is a flowchart describing a method of checking whether a data input and output path and a memory cell are poor within the memory system according to an embodiment of the present disclosure.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

A “logic bit set” may mean a combination of logic levels of bits included in a signal. When a logic level of each of the bits included in the signal is changed, a logic bit set of the signal may be differently set. For example, if two bits are included in a signal, a logic bit set of the signal may be set as a first logic bit set when logic levels of the two bits included in the signal are a “logic low level” and a “logic low level”, and may be set as a second logic bit set when logic levels of the two bits included in the signal are a “logic low level”, and a “logic high level.”

Hereafter, the present disclosure will be described in more detail through embodiments. The embodiments are only used to exemplify the present disclosure, and the scope of the present disclosure is not limited by the embodiments.

Embodiments of the present disclosure provide a semiconductor device performing tests and a test method of the semiconductor device.

According to embodiments of the present disclosure, it is possible to integrally perform cell tests on micro bumps, TSVs, a memory controller, and all memory cells in addition to an input and output (IO) path test on a semiconductor device by using a loopback test path.

Furthermore, according to an embodiment of the present disclosure, it is possible to check the integrity of substantial write and read operations for a memory cell array by performing only a cell test operation without performing an IO path test on a semiconductor device while using a loopback test path.

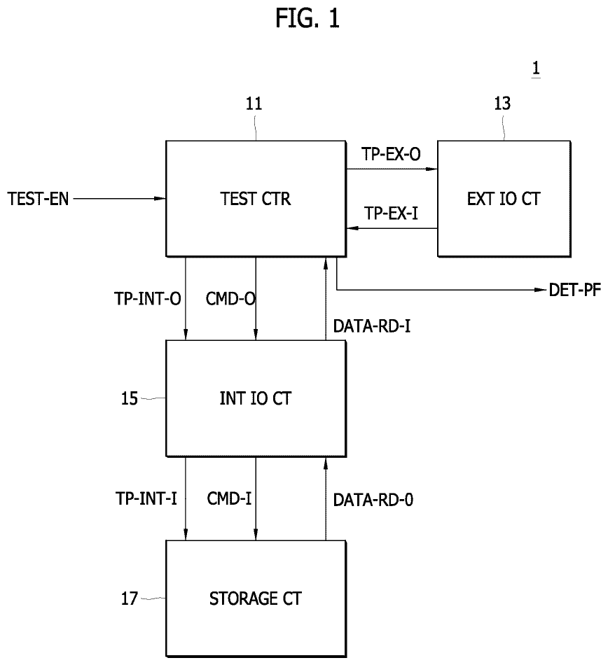

FIG. 1 is a block diagram illustrating a semiconductor device according to an embodiment of the present disclosure.

As illustrated in FIG. 1, the semiconductor device 1 may include a test control circuit (TEST CTR) 11, an external IO circuit (EXT IO CT) 13, an internal IO circuit (INT IO CT) 15, and a storage circuit (STORAGE CT) 17.

The test control circuit 11 may generate an external output test pattern TP-EX-O based on a test enable signal TEST-EN. The test control circuit 11 may sequentially generate the external output test pattern TP-EX-O having a first pattern for a write operation and the external output test pattern TP-EX-O having a second pattern for a read operation. The test control circuit 11 may generate an internal output test pattern TP-INT-O and an output command signal CMD-O based on an external input test pattern TP-EX-I. The test control circuit 11 may generate a check result signal DET-PF based on whether the external output test pattern TP-EX-O and input read data DATA-RD-I are identical with each other.

The external IO circuit 13 may generate the external input test pattern TP-EX-I by performing a loopback operation based on the external output test pattern TP-EX-O. The loopback operation may be defined as an operation of receiving the external output test pattern TP-EX-O that is output from the external IO circuit 13 being received through a reception path within the same circuit again.

The internal IO circuit 15 may generate the internal input test pattern TP-INT-I based on the internal output test pattern TP-INT-O. The internal IO circuit 15 may generate an input command signal CMD-I based on the output command signal CMD-O. The internal IO circuit 15 may output output read data DATA-RD-O as the input read data DATA-RD-I based on the output read data DATA-RD-O. In an embodiment of the present disclosure, the operation that is performed in the internal IO circuit 15 may follow an internal loopback path that is performed within a physical area. Internal loopback may be defined as an operation of checking only a transmission and reception circuit within a chip without passing through an external path, such as a micro bump, a TSV, and an interposer. In an embodiment of the present disclosure, the operation that is performed in the internal IO circuit 15 may include a cell test by including substantial write and read operations for memory cells.

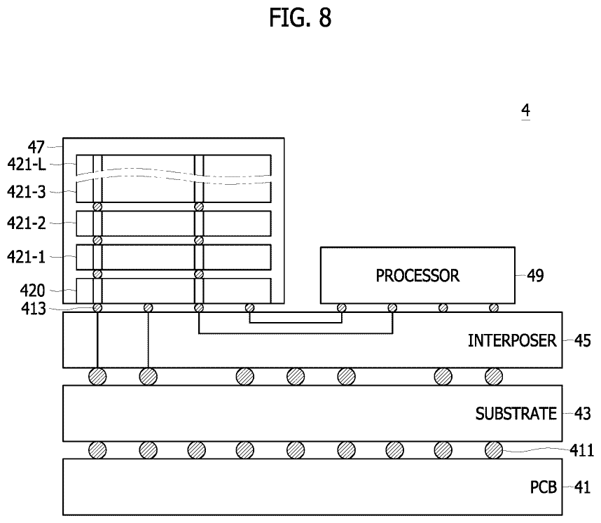

The storage circuit 17 may store an internal input test pattern TP-INT-I based on the internal input test pattern TP-INT-I and the input command signal CMD-I. The storage circuit 17 may extract the output read data DATA-RD-O based on the internal input test pattern TP-INT-I and the input command signal CMD-I. For example, the storage circuit 17 may include die cores (e.g., 421-1 to 421-L in FIG. 8) or a memory cell array. The memory cell array has a structure in which a plurality of memory cells has been arranged in row and column directions, and may perform a role of storing data in a selected memory cell based on an address and a command that are applied from the outside or inside of the semiconductor device or outputting data stored in the memory cell array.

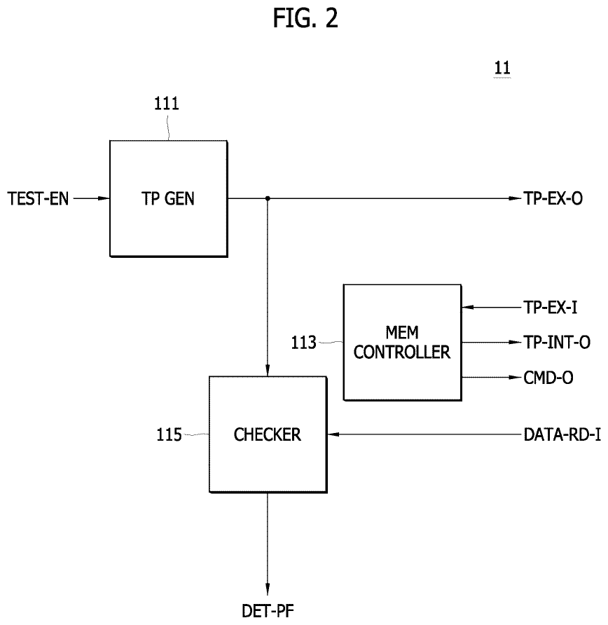

FIG. 2 is a block diagram illustrating a block diagram of the test control circuit 11 according to an embodiment of the present disclosure.

As illustrated in FIG. 2, the test control circuit 11 may include a test pattern generation circuit (TP GEN) 111, a memory controller (MEM CONTROLLER) 113, and a check circuit (CHECKER) 115.

The test pattern generation circuit 111 may generate the external output test pattern TP-EX-O based on the test enable signal TEST-EN. More specifically, the test pattern generation circuit 111 may sequentially generate the external output test pattern TP-EX-O having a first pattern for a write operation and the external output test pattern TP-EX-O having a second pattern for a read operation.

The memory controller 113 may generate the internal output test pattern TP-INT-O based on the external input test pattern TP-EX-I. The memory controller 113 may generate the output command signal CMD-O based on the external input test pattern TP-EX-I. The memory controller 113 may convert a command, an address, and data that are received from the outside of the semiconductor device into an internal control signal by interpreting the command, the address, and the data, and may perform a function that controls access to a memory cell area based on the internal control signal.

The check circuit 115 may generate the check result signal DET-PF based on whether the external output test pattern TP-EX-O and the input read data DATA-RD-I are identical with each other. In an embodiment of the present disclosure, the external output test pattern TP-EX-O may include write data composed of a logic bit set. More specifically, when write data and the input read data DATA-RD-I are identical with each other, the check circuit 115 may output the check result signal DET-PF indicating that all of external transmission and reception paths including micro bumps, TSVs, and an interposer, including a transmission and reception circuit within the semiconductor device 1, the data IO path of the semiconductor device 1, and a data IO path toward the outside of the semiconductor device 1, are normal. In an embodiment of the present disclosure, a plurality of signals being identical may include a case in which their logic bit sets are the same. For example, if a write data signal includes a bit pattern of ‘100101’, and an input read data signal also includes a bit pattern of ‘100101’, the two signals may be regarded as identical.

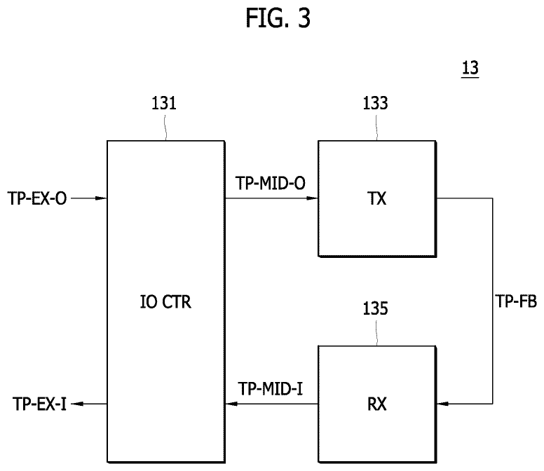

FIG. 3 is a block diagram illustrating a block diagram of the external IO circuit (EXT IO CT) 13 according to an embodiment of the present disclosure.

As illustrated in FIG. 3, the external IO circuit 13 may include an IO control circuit (IO CTR) 131, a transmitter (TX) 133, and a receiver (RX) 135.

The IO control circuit 131 may generate a middle output test pattern TP-MID-O based on the external output test pattern TP-EX-O. More specifically, the IO control circuit 131 may output the middle output test pattern TP-MID-O to the transmitter 133 by performing a matching processing operation based on the external output test pattern TP-EX-O. The IO control circuit 131 may generate the external input test pattern TP-EX-I based on a middle input test pattern TP-MID-I. More specifically, the IO control circuit 131 may output the external input test pattern TP-EX-I to the memory controller 113 by performing a matching processing operation based on the middle input test pattern TP-MID-I. In an embodiment of the present disclosure, the IO control circuit 131 may include a die-to-die physical layer (D2D PHY). The IO control circuit 131 includes the D2D PHY. The D2D PHY performs an interface function between dies, and may play a role of securing signal integrity on a loopback test path by performing an operation of matching and restoring a transmission signal and a reception signal after the start of a test operation. In an embodiment of the present disclosure, the matching processing operation may be defined as an operation of transmitting an address, a command, and data that are received from a physical interface area (PHY) to a subsequent circuit through alignment, conversion, clock synchronization, and amplification based on electrical characteristics and a logical structure

The transmitter 133 may generate a feedback test pattern TP-FB based on the middle output test pattern TP-MID-O. The receiver 135 may generate the middle input test pattern TP-MID-I based on the feedback test pattern TP-FB. More specifically, the transmitter 133 and the receiver 135 may perform loopback operations of transmitting and receiving the feedback test pattern TP-FB.

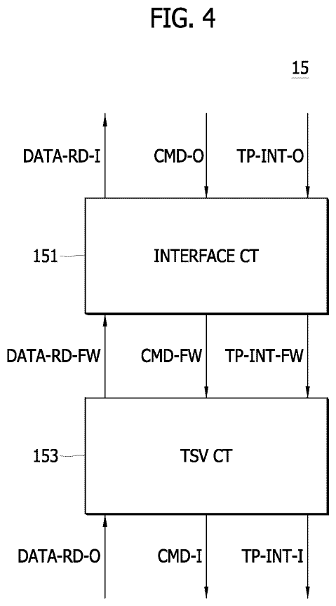

FIG. 4 is a block diagram illustrating a block diagram of the internal IO circuit 15 according to an embodiment of the present disclosure.

As illustrated in FIG. 4, the internal IO circuit 15 may include an interface circuit (INTERFACE CT) 151 and a through silicon via (TSV) circuit (TSV CT) 153.

The interface circuit 151 may generate an internal forward test pattern TP-INT-FW based on the internal output test pattern TP-INT-O. More specifically, the interface circuit 151 may output the internal output test pattern TP-INT-O as the internal forward test pattern TP-INT-FW by performing a matching processing operation based on the internal output test pattern TP-INT-O. The interface circuit 151 may generate a forward command signal CMD-FW based on the output command signal CMD-O. The interface circuit 151 may output the output command signal CMD-O as the forward command signal CMD-FW by performing a matching processing operation based on the output command signal CMD-O. The interface circuit 151 may output forward read data DATA-RD-FW as the input read data DATA-RD-I by performing a matching processing operation based on the forward read data DATA-RD-FW. More specifically, the interface circuit 151 may output the forward read data DATA-RD-FW as the input read data DATA-RD-I by performing a matching processing operation based on the forward read data DATA-RD-FW. In an embodiment of the present disclosure, the interface circuit 151 may include a DDR PHY interface (DFI). The interface circuit 151 including the DFI is an interface between the memory controller 113 and the physical layer PHY, and may perform a function that defines a standardized signal protocol for a transmission command, an address, a control signal, and data. In an embodiment of the present disclosure, the interface circuit 151 including the DFI may be used as an interface that performs matching processes on an internal instruction and data that are output from the memory controller 113 and transmitting the internal instruction and the data.

The TSV circuit 153 may output the internal input test pattern TP-INT-I based on the internal forward test pattern TP-INT-FW. The TSV circuit 153 may output the forward read data DATA-RD-FW based on the output read data DATA-RD-O. The TSV circuit 153 may output the forward command signal CMD-FW as the input command signal CMD-I based on the forward command signal CMD-FW. In an embodiment of the present disclosure, the TSV circuit 153 may include a TSV area. In an embodiment of the present disclosure, the TSV circuit 153 including the TSV area may perform a role of transmitting a test pattern generated by the memory controller 113 to the storage circuit 17 or transmitting data restored from the storage circuit 17 to the memory controller 113 again.

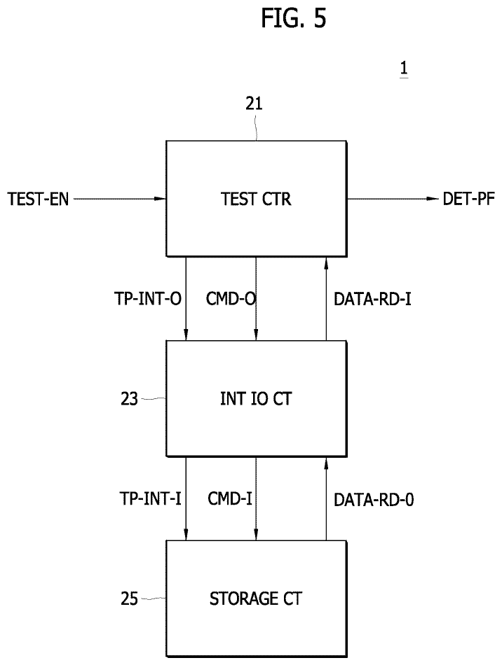

FIG. 5 is a block diagram illustrating a block diagram of the semiconductor device 1 according to an embodiment of the present disclosure.

As illustrated in FIG. 5, the semiconductor device 1 may include a test control circuit (TEST CTR) 21, an internal IO circuit (INT IO CT) 23, and a storage circuit (STORAGE CT) 25.

The test control circuit 21 may generate an internal output test pattern TP-INT-O and an output command signal CMD-O based on a test enable signal TEST-EN. The test control circuit 21 may sequentially generate an external output test pattern TP-EX-O having a first pattern for a write operation and the external output test pattern TP-EX-O having a second pattern for a read operation. In an embodiment of the present disclosure, the external output test pattern TP-EX-O may include write data composed of a logic bit set. The test control circuit 21 may generate a check result signal DET-PF based on whether write data and input read data DATA-RD-I are identical with each other.

The internal IO circuit 23 may generate an internal input test pattern TP-INT-I based on the internal output test pattern TP-INT-O. The internal IO circuit 23 may generate an input command signal CMD-I based on the output command signal CMD-O. The internal IO circuit 23 may output the input read data DATA-RD-I based on output read data DATA-RD-O.

The storage circuit 25 may store the internal input test pattern TP-INT-I based on the internal input test pattern TP-INT-I and the input command signal CMD-I. The storage circuit 25 may extract the output read data DATA-RD-O based on the internal input test pattern TP-INT-I and the input command signal CMD-I.

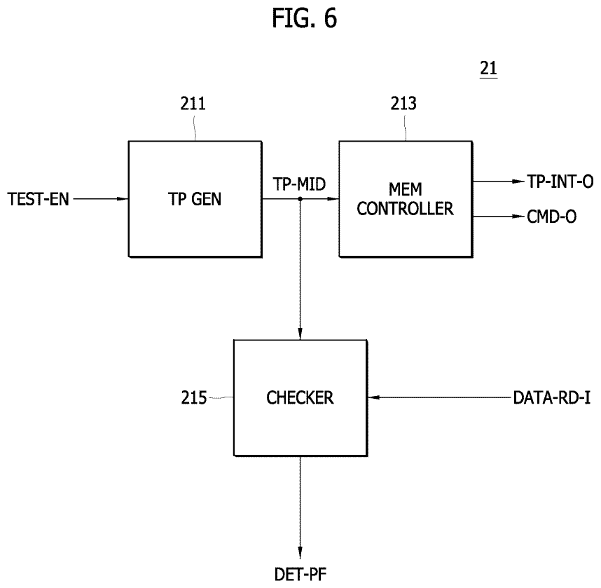

FIG. 6 is a block diagram illustrating a block diagram of the test control circuit 21 according to an embodiment of the present disclosure.

As illustrated in FIG. 6, the test control circuit 21 may include a test pattern generation circuit (TP GEN) 211, a memory controller (MEM CONTROLLER) 213, and a check circuit (CHECKER) 215.

The test pattern generation circuit 211 may generate a middle test pattern TP-MID based on the test enable signal TEST-EN. More specifically, the test pattern generation circuit 211 may sequentially generate the middle test pattern TP-MID having a first pattern for a write operation and the middle test pattern TP-MID having a second pattern for a read operation.

The memory controller 213 may generate the internal output test pattern TP-INT-O based on the middle test pattern TP-MID. The memory controller 213 may generate the output command signal CMD-O based on the middle test pattern TP-MID. The memory controller 213 may perform a function that converts a command, an address, and data received from the outside of the semiconductor device into an internal control signal by interpreting the command, the address, and the data and that controls access to a memory cell area.

The check circuit 215 may generate the check result signal DET-PF based on whether the middle test pattern TP-MID and the input read data DATA-RD-I are identical with each other. More specifically, when the middle test pattern TP-MID and the input read data DATA-RD-I are identical with each other, the check circuit 215 may output the check result signal DET-PF indicating that a connection of all external transmission and reception paths including micro bumps, TSVs, and an interposer, including a transmission and reception circuit within the semiconductor device 1, the data IO path of the semiconductor device 1, and a data IO path toward the outside of the semiconductor device 1, is normal.

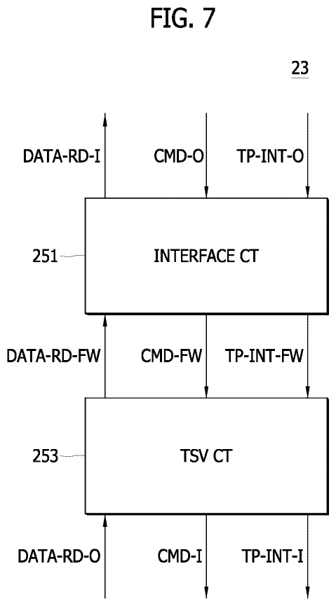

FIG. 7 is a block diagram illustrating a block diagram of the internal IO circuit 23 according to an embodiment of the present disclosure.

As illustrated in FIG. 7, the internal IO circuit 23 may include an interface circuit (INTERFACE CT) 251 and a TSV circuit (TSV CT) 253.

The interface circuit 251 may generate an internal forward test pattern TP-INT-FW based on the internal output test pattern TP-INT-O. More specifically, the interface circuit 251 may output the internal output test pattern TP-INT-O as the internal forward test pattern TP-INT-FW by performing a matching processing operation based on the internal output test pattern TP-INT-O. The interface circuit 251 may generate a forward command signal CMD-FW based on the output command signal CMD-O. The interface circuit 251 may output the output command signal CMD-O as the forward command signal CMD-FW by performing a matching processing operation based on the output command signal CMD-O. The interface circuit 251 may output forward read data DATA-RD-FW as the input read data DATA-RD-I by performing a matching processing operation based on the forward read data DATA-RD-FW. More specifically, the interface circuit 251 may output the forward read data DATA-RD-FW as the input read data DATA-RD-I by performing a matching processing operation based on the forward read data DATA-RD-FW. In an embodiment of the present disclosure, the interface circuit 251 may include a DDR PHY Interface (DFI). The interface circuit including the DFI is an interface between the memory controller 213 and a physical layer PHY, and may perform a function that defines a standardized signal protocol for the transmission of a command, an address, a control signal, and data. In an embodiment of the present disclosure, the interface circuit including the DFI may be used as an interface that transmits an internal instruction and data that are output from the memory controller 213 to a PHY circuit.

The TSV circuit 253 may output the internal input test pattern TP-INT-I based on the internal forward test pattern TP-INT-FW. The TSV circuit 253 may output the forward read data DATA-RD-FW based on the output read data DATA-RD-O. The TSV circuit 253 may output the forward command signal CMD-FW as the input command signal CMD-I based on the forward command signal CMD-FW. In an embodiment of the present disclosure, the TSV circuit 253 may include a TSV area. The TSV circuit 253 including the TSV area may provide an electrical connection path that vertically transmits an internal instruction and data that are transmitted through the DFI interface of the base die 420 to a plurality of die cores. In an embodiment of the present disclosure, the TSV circuit 253 including the TSV area may perform a role of transmitting a test pattern generated by the memory controller 213 to the storage circuit 25 or transmitting data restored from the storage circuit 25 to the memory controller 213 again.

FIG. 8 illustrates a block diagram of a memory system 4 according to an embodiment of the present disclosure.

As illustrated in FIG. 8, the memory system 4 may include a printed circuit board (PCB) 41, a substrate 43, an interposer 45, a memory device 47, and a processor 49.

The PCB 41 connects several electronic components in order to form an electronic circuit (not illustrated). The electronic circuit may include a memory system 4. A copper layer, a solder mask and a silk screen may be formed on the PCB 41. A circuit path that transmits a signal or power is formed in the copper layer. In an embodiment, the solder mask prevents or mitigates damage to the circuit and protects a specific region in which components may be soldered. Furthermore, in an embodiment, the silk screen indicates a position or information of an electronic component in the form of characters or symbols printed on a surface of the PCB 41.

The substrate 43 is formed over the PCB 41 through bump pads (e.g., 411), and may mechanically support the interposer 45, the memory device 47, and the processor 49. The substrate 43 may be used as an insulator as a material, that is, a physical base for the PCB 41, in general. The material of the substrate 43 includes FR4, that is, an insulator made of glass fiber and epoxy resin, ceramics which can withstand a high temperature and is commonly used in a high frequency circuit or a high temperature environment due to its thermal conductivity, and polyimide which is used as a base material for a flexible PCB due to its flexible characteristic.

The interposer 45 is formed over the substrate 43 through bump pads, and may include wires that connect electronic components (e.g., the memory device 47 and the processor 49) with unmatched foam factors or pin arrangements. The interposer 45 may convert signals for communication in different interfaces (e.g., DDR, HBM, and PCIe). In an embodiment of the present disclosure, the interposer may be an area which may be included in a path until the feedback test pattern TP-FB output by the transmitter 133 is received by the receiver 135 in a process for a loopback operation of the external IO circuit 13.

The memory device 47 is formed over the interposer 45 through micro bump pads (e.g., 413). The memory device 47 may store data applied by the processor 49 or output data stored in the memory device 47 to the processor 49, under the control of the processor 49. The memory device 47 includes a base die 420 and the plurality of core dies 421-1 to 421-L. The plurality of core dies 421-1 to 421-L may be stacked on or over the base die 420 through the micro bump pads 413. The base die 420 and the plurality of core dies 421-1 to 421-L are vertically connected through TSVs.

In an embodiment of the present disclosure, the base die 420 may include the test control circuit 21, the external IO circuit 13, and the internal IO circuit 23. In an embodiment of the present disclosure, the base die 420 may include the test control circuit 21 and the internal IO circuit 23. The base die 420, in an embodiment, controls data to be efficiently transmitted between the processor 49 and the die cores 421-1 to 421-L. Each of the die cores 421-1 to 421-L may include a plurality of channel areas (e.g., 8 channel areas or 32 channel areas) that independently operate. Each of the plurality of channel areas is assigned a channel that independently operates, and receives or transmits data. The number L of die cores 421-1 to 421-L may be 4, 8, or 32. For example, when each of the die cores 421-1 to 421-12 has 8 channels, each of the die cores 421-1 to 421-4, the die cores 421-5 to 421-8, and the die cores 421-9 to 421-12 includes 32 channel areas, and may transmit and receive data to and from the processor 49 in a rank unit including 32 channels. In an embodiment, the number of L of die cores may be greater than 32.

Each of the die cores 421-1 to 421-L may store a test pattern and extract a test pattern. For example, each of the die cores 421-1 to 421-L may store the internal input test pattern TP-INT-I based on the internal input test pattern TP-INT-I and the input command signal CMD-I, and may output the output read data DATA-RD-O based on the internal input test pattern TP-INT-I and the input command signal CMD-I. More specifically, the die cores 421-1 to 421-L may be defined as a component that includes a memory cell array and a peripheral circuit and that performs a main memory function of a storage device. The plurality of die cores 421-1 to 421-L may independently perform data IO by receiving a control signal and a data signal from the base die 420. For example, in an embodiment of the present disclosure, the die cores 421-1 to 421-L that function as the storage circuit 25 may perform real operation check at a memory cell level by storing or restoring again data based on an internal test pattern that is transmitted through the test control circuit 21.

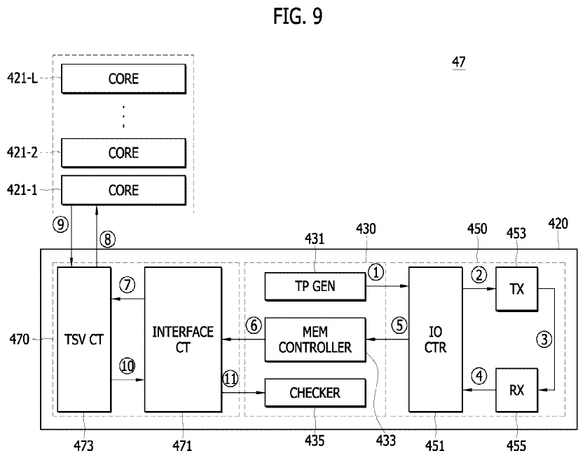

FIG. 9 illustrates the paths of a test pattern in the memory device 47 according to an embodiment of the present disclosure.

As illustrated in FIG. 9, the memory device 47 may include the base die 420 and the plurality of die cores 421-1 to 421-L.

The base die 420 may include a test control circuit 430, an external IO circuit 450, and an internal IO circuit 470. The test control circuit 430 may include a test pattern generation circuit (TP GEN) 431, a memory controller (MEM CONTROLLER) 433, and a check circuit (CHECKER) 435. The external IO circuit 450 may include an IO control circuit (IO CTR) 451, a transmitter (TX) 453, and a receiver (RX) 455. The internal IO circuit 470 may include an interface circuit (INTERFACE CT) 471 and a TSV circuit (TSV CT) 473. A test pattern that is generated by the test pattern generation circuit 431 within the test control circuit 430 may be transmitted through a path \textcircled{4} from the receiver 455 to the IO control circuit 451 again via a path \textcircled{1} to the IO control circuit 451 within the external IO circuit 450, a path \textcircled{2} from the IO control circuit 451 to the transmitter 453, and a path \textcircled{3} from the transmitter 453 to the receiver 455. The test pattern received by the IO control circuit 451 may be transmitted to a path \textcircled{8} to the plurality of die cores via a path \textcircled{5} to the memory controller 433 within the test control circuit 430, a path \textcircled{6} from the memory controller 433 to the interface circuit 471 within the internal IO circuit 470, and a path \textcircled{7} from the interface circuit 471 to the TSV circuit 473. The test pattern that passes through the plurality of die cores may be transmitted through a path \textcircled{11} to the check circuit 435 within the test control circuit 430 again via a path \textcircled{9} to the TSV circuit 473 within the internal IO circuit 470 and a path \textcircled{10} from the TSV circuit 473 to the interface circuit 471. The test pattern generation circuit 431 within the test control circuit 430 may sequentially generate a test pattern having a first pattern for a write operation and a test pattern having a second pattern. In an embodiment of the present disclosure, the test patterns having the first pattern and the second pattern may be sequentially transmitted along the paths illustrated in FIG. 9. In an embodiment of the present disclosure, a loopback operation that is performed in the external IO circuit 450 may correspond to an external loopback path because the loopback operation is performed via an external transmission and reception path including the interposer, the micro bumps, and the TSVs. In an embodiment of the present disclosure, the operation that is performed in the internal IO circuit 470 may follow an internal loopback path that is performed within a physical area. In an embodiment of the present disclosure, the operation that is performed in the internal IO circuit 470 may include a cell test because the operation includes write and read operations for a memory cell array.

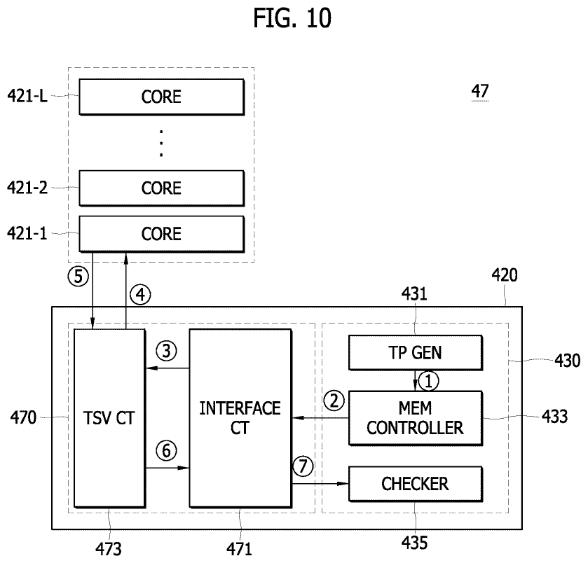

FIG. 10 illustrates the paths of a test pattern in the memory device 47 according to an embodiment of the present disclosure.

As illustrated in FIG. 10, the memory device 47 may include a base die 420 and a plurality of die cores 421-1 to 421-L.

The base die 420 may include a test control circuit 430 and an internal IO circuit 470. The test control circuit 430 may include a test pattern generation circuit (TP GEN) 431, a memory controller (MEM CONTROLLER) 433, and a check circuit (CHECKER) 435. The internal IO circuit 470 may include an interface circuit (INTERFACE CT) 471 and a TSV circuit (TSV CT) 473.

A test pattern that is generated by the test pattern generation circuit 431 within the test control circuit 430 may be transmitted to a path \textcircled{4} to the plurality of die cores via a path \textcircled{1} to the memory controller 433 within the test control circuit 430, a path \textcircled{2} from the memory controller 433 to the interface circuit 471 within the internal IO circuit 470, and a path \textcircled{3} from the interface circuit 471 to the TSV circuit 473. The test pattern that passes through the plurality of die cores may be transmitted through a path \textcircled{7} to the check circuit 435 within the test control circuit 430 again via a path \textcircled{5} to the TSV circuit 473 within the internal IO circuit 470 and a path \textcircled{6} from the TSV circuit 473 to the interface circuit 471. The test pattern generation circuit 431 within the test control circuit 430 may sequentially generate a test pattern having a first pattern for a write operation and a test pattern having a second pattern. In an embodiment of the present disclosure, the test patterns having the first pattern and the second pattern may be sequentially transmitted along the paths illustrated in FIG. 10. In an embodiment of the present disclosure, the operation that is performed in the internal IO circuit 470 may follow an internal loopback path that is performed within a physical area. In an embodiment of the present disclosure, the operation that is performed in the internal IO circuit 470 may include a cell test because the operation includes substantial write and read operations for a memory cell array.

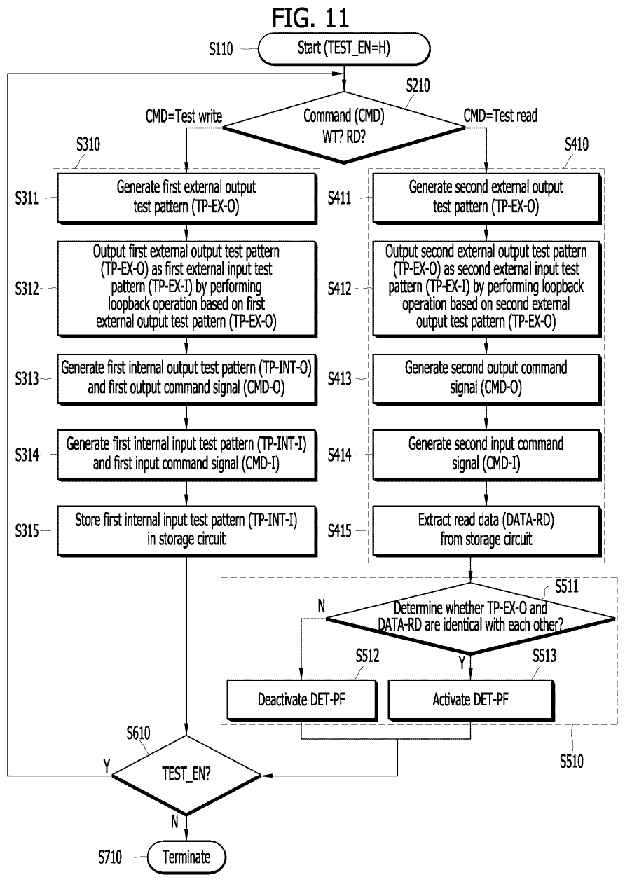

FIG. 11 is a flowchart describing a method of checking whether a data IO path within a memory system and a memory cell are poor by using a loopback path according to an embodiment of the present disclosure. In the present disclosure, a “poor” connection refers to a state in which a transmitted signal is not properly delivered to the receiving side or its electrical characteristics are degraded such that it cannot be correctly recognized. This includes, for example, cases of short circuits, opens, or increased resistance occurring in paths such as an interposer, TSVs, or micro-bumps.

The method of checking whether a data IO path within a memory system and a memory cell are poor, which is performed by using a loopback path without an external device, according to an embodiment of the present disclosure may include a process S110 of entering a test mode as the test enable signal TEST-EN is activated, a first operation determination process S210 of determining whether a command signal CMD corresponds to a write operation or a read operation, a first write process S310, a first read process S410, a first check process S510, and a first termination determination process S610.

The first write process S310 may be performed when the command signal CMD is determined to correspond to a write operation. The first write process S310 may include a process S311 of generating the first external output test pattern TP-EX-O based on the test enable signal TEST-EN. The first write process S310 may include a process S312 of outputting the first external output test pattern TP-EX-O as the first external input test pattern TP-EX-I by performing a loopback operation based on the first external output test pattern TP-EX-O. The first write process S310 a process S313 of generating the first internal output test pattern TP-INT-O and the first output command signal CMD-O based on the first external input test pattern TP-EX-I. The first write process S310 may include a process S314 of generating the first internal input test pattern TP-INT-I based on the first internal output test pattern TP-INT-O and generating the first input command signal CMD-I based on the first output command signal CMD-O. The first write process S310 may include a process S315 of storing a test pattern for the write operation in the storage circuit 17 based on the first internal input test pattern TP-INT-I and the first input command signal CMD-I.

The first read process S410 may be performed when the command signal CMD is determined to correspond to the read operation. The first read process S410 may include a process S411 of generating the second external output test pattern TP-EX-O based on the test enable signal TEST-EN. The first read process S410 may include a process S412 of outputting the second external output test pattern TP-EX-O as the second external input test pattern TP-EX-I by performing a loopback operation based on the second external output test pattern TP-EX-O. The first read process S410 may include a process S413 of generating the second output command signal CMD-O based on the second external input test pattern TP-EX-I. The first read process S410 may include the process S414 of generating the second input command signal CMD-I based on the second output command signal CMD-O. The first read process S410 may include a process S415 of extracting the read data DATA-RD from the storage circuit 17 based on the second input command signal CMD-I.

The first check process S510 may be defined as a process of checking whether a data IO path and a memory cell are poor by comparing whether the first external output test pattern TP-EX-O and the read data DATA-RD are identical with each other and outputting the check result signal DET-PF after the first read process S410 is completed. The first check process S510 may include a process S511 of determining whether the first external output test pattern TP-EX-O and the read data DATA-RD are identical with each other. The first check process S510 may include a process S512 of checking whether a data IO path and a memory cell are poor by activating the check result signal DET-PF when the first external output test pattern TP-EX-O and the read data DATA-RD are identical with each other. The first check process S510 may include a process S513 of checking whether a data IO path and a memory cell are poor by deactivating the check result signal DET-PF when the first external output test pattern TP-EX-O and the read data DATA-RD are different from each other.

The first termination determination process S610 may be defined as a process of entering the first operation determination process S210 again when the test enable signal TEST-EN is still activated and entering a process S710 of terminating the test mode when the test enable signal TEST-EN is deactivated, after the first write process S310 or the first check process S510 is completed.

Accordingly, a cell test can be integrally performed on micro bumps, TSVs, a memory controller, and all memory cells in addition to the IO path test of the semiconductor device 1 by using a loopback test path.

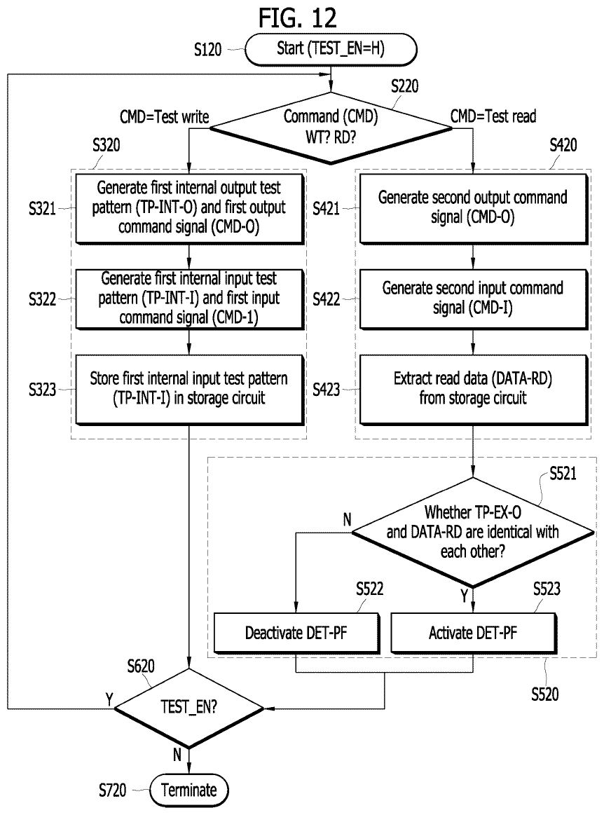

FIG. 12 is a flowchart describing a method of checking whether a data IO path and a memory cell are poor within a memory system according to an embodiment of the present disclosure. The method of checking whether a data IO path and a memory cell are poor, which is performed by using a loopback path without an external device, according to an embodiment of the present disclosure may include a process S120 of entering a test mode as the test enable signal TEST-EN is activated, a second operation determination process S220 of determining whether the command signal CMD corresponds to a write operation or a read operation, a second write process S320, a second read process S420, a second check process S520, and a second termination determination process S620.

The second write process S320 may be performed when the command signal CMD is determined to correspond to a write operation. The second write process S320 may include a process S321 of generating the first internal output test pattern TP-INT-O based on the test enable signal TEST-EN, a process S322 of generating the first internal input test pattern TP-INT-I based on the first internal output test pattern TP-INT-O, and a process S323 of storing write data in the storage circuit 17 based on the first internal input test pattern TP-INT-I.

The second read process S420 may be performed when the command signal CMD is determined to correspond to a read operation. The second read process S420 may include a process S421 of generating the second output command signal CMD-O based on the test enable signal TEST-EN. The second read process S420 may include a process S422 of generating the second input command signal CMD-I based on the second output command signal CMD-O. The second read process S420 may include a process S423 of extracting the read data DATA-RD from the storage circuit 17 based on the second input command signal CMD-O.

The second check process S520 may be defined as a process of checking whether a data IO path and a memory cell are poor by comparing whether the second external output test pattern TP-EX-O and the read data DATA-RD are identical with each other and outputting the check result signal DET-PF after the second read process S420 is completed. The second check process S520 may include a process S521 of determining whether the first external output test pattern TP-EX-O and the read data DATA-RD are identical with each other. The second check process S520 may include a process S522 of activating the check result signal DET-PF when the second external output test pattern TP-EX-O and the read data DATA-RD are identical with each other and a process S523 of deactivating the check result signal DET-PF when the second external output test pattern TP-EX-O and the read data DATA-RD are different from each other.

The second termination determination process S620 may be defined as a process of entering the second operation determination process S220 when the test enable signal TEST-EN is still activated and entering a process S720 of terminating the test mode when the test enable signal TEST-EN is deactivated, after the second write process S320 or the second check process is completed.

Accordingly, the integrity of substantial write and read operations for a memory cell array can be checked by performing only a cell test operation without performing an IO path test on the semiconductor device 1 while using a loopback test path.

The embodiments of the present disclosure have been described so far. The disclosed embodiments should be considered from a descriptive viewpoint, not from a limitative viewpoint.

What is claimed is:

1. A semiconductor device comprising:
a test control circuit configured to generate an external output test pattern based on a test enable signal, configured to generate an internal output test pattern and an output command signal based on an external input test pattern, and configured to generate a check result signal based on input read data;
an external input and output (IO) circuit configured to generate the external input test pattern by performing a loopback operation based on the external output test pattern;
an internal IO circuit configured to generate an internal input test pattern based on the internal output test pattern, configured to generate an input command signal based on the output command signal, and configured to output the input read data based on output read data; and
a storage circuit configured to store the internal input test pattern based on the internal input test pattern and the input command signal and configured to extract the output read data based on the internal input test pattern and the input command signal.

2. The semiconductor device of claim 1, wherein the test control circuit comprises:
a test pattern generation circuit configured to generate the external output test pattern based on the test enable signal;
a memory controller configured to generate the internal output test pattern and the output command signal based on the external input test pattern; and
a check circuit configured to generate the check result signal based on whether the external input test pattern and the input read data are identical with each other.

3. The semiconductor device of claim 2, wherein the test control circuit sequentially generates the external output test pattern having a first pattern for a write operation and the external output test pattern having a second pattern for a read operation.

4. The semiconductor device of claim 1, wherein the external IO circuit comprises:
an IO control circuit configured to generate a middle output test pattern based on the external output test pattern and configured to generate the external input test pattern based on a middle input test pattern;
a transmitter configured to generate a feedback test pattern based on the middle output test pattern; and
a receiver configured to generate the middle input test pattern based on the feedback test pattern.

5. The semiconductor device of claim 1, wherein the loopback operation is an operation of receiving the external output test pattern output from the external IO circuit being received again through a reception path within the external IO circuit.

6. The semiconductor device of claim 1, wherein the internal IO circuit comprises:
an interface circuit configured to generate an internal forward test pattern based on the internal output test pattern, configured to generate a forward command signal based on the output command signal, and configured to generate the input read data based on forward read data; and
a through silicon via (TSV) circuit configured to output the internal input test pattern based on the internal forward test pattern, configured to output the input command signal based on the forward command signal, and configured to output the forward read data based on the output read data.

7. A memory system comprising:
a plurality of die cores stacked over a base die,
the base die comprises:
a test control circuit configured to generate an external output test pattern based on a test enable signal, configured to generate an internal output test pattern and an output command signal based on an external input test pattern, and configured to generate a check result signal based on input read data;
an external input and output (IO) circuit configured to generate the external input test pattern by performing a loopback operation based on the external output test pattern; and
an internal IO circuit configured to generate an internal input test pattern based on the internal output test pattern, configured to generate an input command signal based on the output command signal, and configured to output the input read data based on output read data,
wherein each of the plurality of die cores stores the internal input test pattern based on the internal input test pattern and the input command signal and outputs the output read data based on the internal input test pattern and the input command signal.

8. The memory system of claim 7, wherein the test control circuit comprises:
a test pattern generation circuit configured to generate the external output test pattern based on the test enable signal;
a memory controller configured to generate the internal output test pattern and the output command signal based on the external input test pattern; and
a check circuit configured to generate the check result signal based on whether the external input test pattern and the input read data are identical with each other.

9. The memory system of claim 8, wherein the test control circuit sequentially generates the external output test pattern having a first pattern for a write operation and the external output test pattern having a second pattern for a read operation.

10. The memory system of claim 7, wherein the external IO circuit comprises:
an IO control circuit configured to generate a middle output test pattern based on the external output test pattern and configured to generate the external input test pattern based on a middle input test pattern;
a transmitter configured to generate a feedback test pattern based on the middle output test pattern; and
a receiver configured to generate the middle input test pattern based on the feedback test pattern.

11. The memory system of claim 7, wherein the loopback operation is an operation of receiving the external output test pattern output from the external IO circuit being received again through a reception path within the external IO circuit.

12. The memory system of claim 7, wherein the internal IO circuit comprises:
an interface circuit configured to generate an internal forward test pattern based on the internal output test pattern, configured to generate a forward command signal based on the output command signal, and configured to generate the input read data based on forward read data; and
a through silicon via (TSV) circuit configured to output the internal input test pattern based on the internal forward test pattern, configured to output the input command signal based on the forward command signal, and configured to output the forward read data based on the output read data.

13. A semiconductor device comprises:
a test control circuit configured to generate an internal output test pattern and an output command signal based on a test enable signal and configured to generate a check result signal based on input read data;
an internal input and output (IO) circuit configured to generate an internal input test pattern based on the internal output test pattern, configured to generate an input command signal based on the output command signal, and configured to output the input read data based on output read data; and
a storage circuit configured to store the internal input test pattern based on the internal input test pattern and the input command signal and configured to output the output read data based on the internal input test pattern and the input command signal.

14. The semiconductor device of claim 13, wherein the test control circuit comprises:
a test pattern generation circuit configured to generate a middle test pattern based on the test enable signal;
a memory controller configured to generate the internal output test pattern and the output command signal based on the middle test pattern; and
a check circuit configured to generate the check result signal based on whether the middle test pattern and the input read data are identical with each other.

15. The semiconductor device of claim 14, wherein the test control circuit sequentially generates the middle test pattern having a first pattern for a write operation and the middle test pattern having a second pattern for a read operation.

16. The semiconductor device of claim 13, wherein the internal IO circuit comprises:
an interface circuit configured to generate an internal forward test pattern based on the internal output test pattern, configured to generate a forward command signal based on the output command signal, and configured to generate the input read data based on forward read data; and
a through silicon via (TSV) circuit configured to output the internal input test pattern based on the internal forward test pattern, configured to output the input command signal based on the forward command signal, and configured to output the forward read data based on the output read data.

17. A memory system comprising:
a plurality of die cores stacked over a base die,
the base die comprises:
a test control circuit configured to generate an internal output test pattern and an output command signal based on a test enable signal and configured to generate a check result signal based on input read data; and
an internal input and output (IO) circuit configured to generate an internal input test pattern based on the internal output test pattern, configured to generate an input command signal based on the output command signal, and configured to output the input read data based on output read data,
wherein each of the plurality of die cores comprises a storage circuit configured to store the internal input test pattern based on the internal input test pattern and the input command signal and configured to output the output read data based on the internal input test pattern and the input command signal.

18. The memory system of claim 17, wherein the test control circuit comprises:
a test pattern generation circuit configured to generate a middle test pattern based on the test enable signal;
a memory controller configured to generate the internal output test pattern and the output command signal based on the middle test pattern; and
a check circuit configured to generate the check result signal based on whether the middle test pattern and the input read data are identical with each other.

19. The memory system of claim 18, wherein the test control circuit sequentially generates the middle test pattern having a first pattern for a write operation and the middle test pattern having a second pattern for a read operation.

20. The memory system of claim 17, wherein the internal IO circuit comprises:
an interface circuit configured to generate an internal forward test pattern based on the internal output test pattern, configured to generate a forward command signal based on the output command signal, and configured to generate the input read data based on forward read data; and
a through silicon via (TSV) circuit configured to output the internal input test pattern based on the internal forward test pattern, configured to output the input command signal based on the forward command signal, and configured to output the forward read data based on the output read data.

21. A method of checking when a data input and output (IO) path and a memory cell are poor, the method comprising:
a first operation determination process of entering a test mode based on a test enable signal and determining whether a command signal corresponds to a write operation or a read operation;
a first write process of generating a test pattern for the write operation and performing a loopback operation when the command signal is determined to correspond to the write operation and storing a test pattern for the write operation in a storage circuit;
a first read process of generating a test pattern for the read operation and performing a loopback operation when the command signal is determined to correspond to the read operation and extracting read data from the storage circuit;
a first check process of performing a check operation of checking whether a data input and output (IO) path and a memory cell are poor by outputting a check result signal based on whether the test pattern for the write operation and the read data are identical with each other when the first read process is completed; and
a first termination determination process of re-entering the first operation determination process when the test enable signal is determined to have been activated and terminating the test mode when the test enable signal is determined to have been deactivated, when the first write process or the first read process is completed.

22. The method of claim 21, wherein the first write process comprises:
generating a first external output test pattern based on the test enable signal;
outputting the first external output test pattern as a first external input test pattern by performing the loopback operation based on the first external output test pattern;
generating a first internal output test pattern and a first output command signal based on the first external input test pattern;
generating a first internal input test pattern based on the first internal output test pattern and generating a first input command signal based on the first output command signal; and
storing the first internal input test pattern in a storage circuit based on the first internal input test pattern and the first input command signal.

23. The method of claim 21, wherein the first read process comprises:
generating a second external output test pattern based on the test enable signal;
outputting the second external output test pattern as a second external input test pattern by performing a loopback operation the second external output test pattern;
generating a second output command signal based on the second external input test pattern;
generating a second input command signal based on the second output command signal; and
extracting the read data from the storage circuit based on the second input command signal.

24. The method of claim 21, wherein the first check process comprises:
determining whether the first external output test pattern and the read data are identical with each other;
checking whether the data IO path and the memory cell are poor by activating the check result signal when the first external output test pattern and the read data are identical with each other; and
checking whether the data IO path and the memory cell are poor by deactivating the check result signal when the first external output test pattern and the read data are different from each other.

25. A method of checking whether a data input and output (IO) path and a memory cell are poor, the method comprising:
a second operation determination process of entering a test mode based on a test enable signal and determining whether a command signal corresponds to a write operation or a read operation;
a second write process of generating a test pattern for the write operation within a semiconductor device and storing write data in a storage circuit when the command signal is determined to correspond to the write operation;
a second read process of generating a test pattern for the read operation within the semiconductor device and extracting read data from the storage circuit when the command signal is determined to correspond to the read operation;
a second check process of performing a check operation of checking whether a data IO path and a memory cell are poor by outputting a check result signal based on whether the write data and the read data are identical with each other when the second read process is completed; and
a second termination determination process of re-entering the second operation determination process when the test enable signal is determined to have been activated and terminating the test mode when the test enable signal is determined to have been deactivated, when the second write process or the second read process is completed.

26. The method of claim 25, wherein the second write process comprises:
generating a first internal output test pattern and a first output command signal based on the test enable signal within the semiconductor device;
generating a first internal input test pattern based on the first internal output test pattern and generating a first input command signal based on the first output command signal; and
storing the first internal input test pattern in the storage circuit based on the first internal input test pattern and the first input command signal.

27. The method of claim 25, wherein the second read process comprises:
generating a second output command signal based on the test enable signal within the semiconductor device;
generating a second input command signal based on the second output command signal; and
extracting the read data from the storage circuit based on the second input command signal.

28. The method of claim 25, wherein the second check process comprises:
determining whether a first internal output test pattern and the read data are identical with each other;
checking whether the data IO path and the memory cell are poor by activating the check result signal when the first internal output test pattern and the read data are identical with each other; and
checking whether the data IO path and the memory cell are poor by deactivating the check result signal when the first internal output test pattern and the read data are different from each other.
